(19) United States
(12) Patent Application Publication
(10) Pub. No.: US 2011/0309467 A1
(43) Pub. Date: Dec. 22, 2011

(54) SEMICONDUCTOR DEVICE AND MANUFACTURING METHOD THEREOF

(75) Inventors: Shin Matsumoto, Osaka-shi (JP); Yutaka Takafuji, Osaka-shi (JP); Yasumori Fukushima, Osaka-shi (JP); Kazuhide Tomiyasu, Osaka-shi (JP); Kenshi Tada, Osaka-shi (JP)

(73) Assignee: SHARP KABUSHIKI KAISHA, Osaka-shi, Osaka (JP)

(21) Appl. No.: 13/141,332

(22) PCT Filed: Nov. 25, 2009
(86) PCT No.: PCT/JP2009/006343

§ 371 Date: Jun. 22, 2011

(30) Foreign Application Priority Data
Mar. 9, 2009 (JP) 2009-055245

(51) Int. Cl. H01L 27/12; H01L 21/762

(52) U.S. Cl. 257/506; 438/458; 257/E27.112; 257/E21.57

(57) ABSTRACT

Disclosed is a semiconductor device including a substrate for bonding (10a), and a semiconductor element part (25aa) which is bonded to the substrate (10a), and in which an element pattern (T) is formed, wherein in a bonded interface between the substrate (10a) and the semiconductor element part (25aa), recessed portions (23a) are formed in at least one of the substrate (10a) and the semiconductor element part (25aa).

### TECHNICAL FIELD

The present disclosure relates to semiconductor devices and manufacturing methods thereof, and in particular, the present invention relates to semiconductor devices and manufacturing methods thereof used for liquid crystal display devices or the like.

### BACKGROUND ART

Liquid crystal display devices in an active-matrix driving system include an active matrix substrate and a counter substrate which are disposed to face each other, and a liquid crystal layer provided between these substrates. Since the active matrix substrate includes, for example, a TFT (Thin Film Transistor) in each pixel in a display region displaying images as a switching element, and a drive circuit, a control circuit, and the like in a non-display region located outside the display region, the active matrix substrate constitutes a semiconductor device.

In recent years, there have been proposed methods of manufacturing semiconductor devices by using device transfer techniques of, after forming a semiconductor element on a silicon substrate, adhering the semiconductor element to a substrate to be transferred.

For example, Patent Document 1 discloses a method of manufacturing a semiconductor device, the method including forming at least a part of an element on a substrate layer, forming a delamination layer, forming a flattening film, forming a die by splitting the substrate layer in a cutting region, laminating the die on the surface of the flattening film, and separating and removing a part of the substrate layer along the delamination layer, wherein the method includes, before the forming the die, forming a recess groove opened to the surface of the flattening film, and having a bottom surface located in a side opposite to the flattening film, and located further from the flattening film than the delamination layer is so that at least a part of the cutting region is included in the bottom surface of the recess groove.

Patent Document 2 discloses a method of transferring a layer from a first wafer to a second wafer, the first wafer including on the surface thereof a zone of weakness determining a layer of a material selected from semiconductor materials whose thickness is closer to or greater than that of a layer to be transferred, the method including contacting surfaces of the two wafers so as to allow the layer whose thickness is closer to or greater than that of the layer to be transferred to contact the second layer, supplying thermal energy for a first time longer than about 30 minutes at a first temperature which is substantially higher than the ambient temperature and is in a range from 200° C. to 400° C., and further supplying thermal energy to raise the temperature higher than the first temperature, thereby removing the layer to be transferred from the first wafer in the zone of weakness.

Patent Document 3 discloses a method of manufacturing a wiring board, the method including forming vial holes in predetermined positions of an insulating sheet made of an insulating porous material containing a thermosetting resin, filling the via holes with a conductive composition containing metal powders to form via hole conductors, and transferring a wiring circuit layer made of a metal foil which has been formed on the surface of a transfer sheet in advance onto the surface of the insulating sheet in which the via hole conductors are formed, and then, optionally stacking multiples ones of the insulating sheet, thereby hardening the thermosetting resin in the insulating sheet.

### PATENT DOCUMENT

PATENT DOCUMENT 1: Japanese Patent Publication No. 2008-66566

PATENT DOCUMENT 2: Japanese Patent Publication No. 2006-74034

PATENT DOCUMENT 3: Japanese Patent Publication No. 2001-15872

### SUMMARY OF THE INVENTION

### Technical Problem

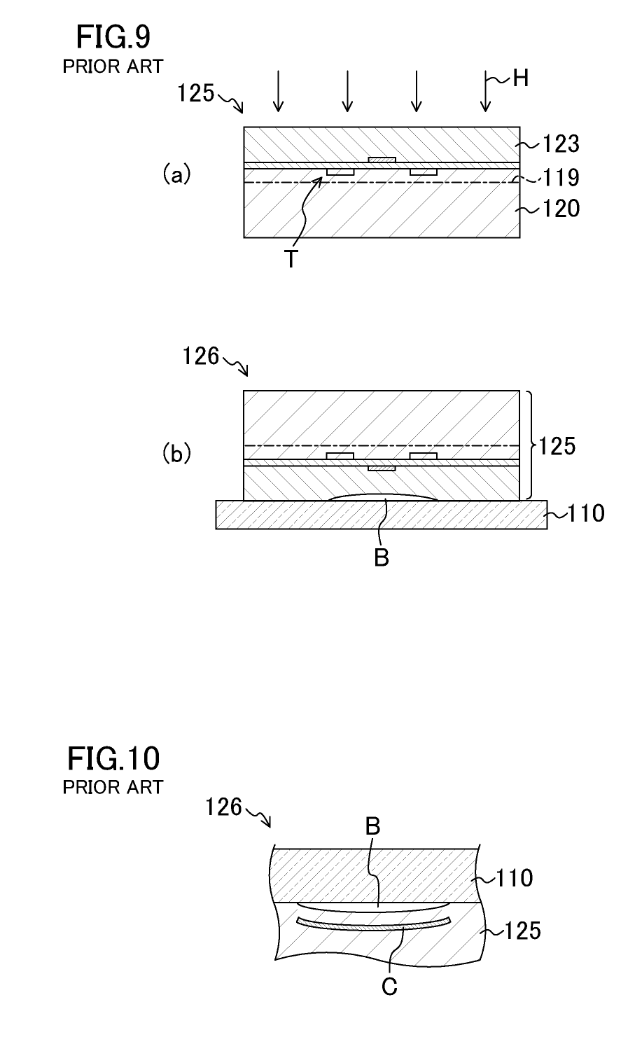

FIG. 9 is a cross-sectional view showing a method of manufacturing a semiconductor device by using the aforementioned conventional device transfer technique, and FIG. 10 is a cross-sectional view of a precursor 126 of the semiconductor device in the method of manufacturing the semiconductor device.

The semiconductor device in which the conventional device transfer technique is used will be manufactured by performing the following processes.

First, as shown in FIG. 9(a), as a semiconductor element, for example, a transistor element T is formed in a silicon substrate 120, and then, a flattening film 123 is formed so as to cover the transistor element T.

Then, hydrogen ions are implanted into the substrate on which the flattening film 123 is formed from a side closer to the flattening film 123, whereby forming a hydrogen implanted layer 119 in the silicon substrate 120 at a predetermined depth to form a silicon die 125.

Besides, as shown in FIG. 9(b), the silicon die 125 is aligned and disposed in a predetermined region in the surface of a glass substrate 110 which is a substrate to be transferred, thereby bonding the silicon die 125 to the surface of the glass substrate 110 by Van der Waals force to form the precursor 126.

Finally, an anneal treatment is performed with respect to the precursor 126, thereby splitting the silicon die 125 bonded to the glass substrate 110 along the hydrogen implanted layer 119.

However, in the conventional manufacturing method, as shown in FIGS. 9(b) and 10, in the precursor 126 in which the silicon die 125 is bonded to the glass substrate 110, an air bubble B may be trapped between the glass substrate 110 and the silicon die 125. The speed of the bonding in the interface between the glass substrate 110 and the silicon die 125 depends on the strength of a bonding energy in the interface between the glass substrate 110 and the silicon die 125. If the strength of the bonding energy varies depending on the location, the bonding processes are performed so that a region where the bonding energy is relatively strong surrounds a region where the bonding energy is relatively weak. Therefore, the glass substrate 110 and the silicon die 125 are bonded to each other with the air bubble B trapped therebetween, thereby causing a problem of deformation of a circuit unit C including such as the transistor element T, as shown in FIG. 10. Although a solution for solving the problem may include a method of bonding substrates (the glass substrate 110 and the silicon die 125) to each other in a vacuum device, or a method of applying a high pressure and a high temperature to the substrate (the silicon die 125) to bond the substrates to each other so that the air bubble B is expelled, such solutions may increase the size of the device, or may cause serious damage to the circuit unit C formed in the silicon die 125 when the high pressure and the high temperature are applied to the silicon die 125.

In view of the foregoing, the present invention has been developed. It is an object of the present invention to easily reduce trapping of air bubbles in the bonded interface, thereby reducing damage to element patterns.

### Solution to the Problem

In order to attain the above object, the present invention is configured such that, in a bonded interface, recessed portions are formed in at least one of a substrate for bonding and a semiconductor element part.

Specifically, a semiconductor device according to the present invention is a semiconductor device including a substrate for bonding, and a semiconductor element part which is bonded to the substrate, and in which an element pattern is formed, wherein in a bonded interface between the substrate and the semiconductor element part, recessed portions are formed in at least one of the substrate and the semiconductor element part.

According to the above configuration, the recessed portions are formed in at least one of the substrate and the semiconductor element part in the bonded interface between the substrate and the semiconductor element part constituting the semiconductor device. Therefore, the recessed portions formed in the bonded interface reduce local unevenness of the bonding energy in the bonded interface. With this feature, only the formation of the recessed portions in at least one of the substrate and the semiconductor element part allows the semiconductor element part to be bonded to the substrate by bonding energy having a relatively predetermined strength in the bonded surface, thereby easily reducing trapping of air bubbles in the bonded interface. The trapping of the air bubbles is reduced in the bonded interface, thereby reducing deformation of the element pattern formed in the semiconductor element part to reduce damage to the element pattern. Therefore, the trapping of the air bubbles can be easily reduced in the bonded interface, thereby making it possible to reduce the damage to the element pattern. Only the formation of the recessed portions in at least one of the substrate and the semiconductor element part causes reduction of the trapping of the air bubbles in the bonded interface, and therefore, it is unnecessary to prepare a vacuum environment or an environment of high pressure and high temperature in order to perform the bonding process, thereby making it possible to simplify a bonding device or shorten a fabrication process.

The recessed portions may communicate with the outside.

According to the above configuration, since the recessed portions communicate with the outside, the air bubbles that may be trapped in the bonded interface are exhausted to the outside, and the trapping of the air bubbles is specifically reduced in the bonded surface.

The recessed portions may be formed by a plurality of groove lines extending in parallel relation to one another.

According to the above configuration, since the recessed portions are the plurality of the groove lines provided so that the groove lines extend in parallel relation to one another, the air bubbles that may be trapped in the bonded interface are specifically exhausted to the outside through the end portion of each of the groove lines.

The recessed portions may not communicate with the outside.

According to the above configuration, the recessed portions do not communicate with the outside, and therefore, trapping of chemicals, dust, and the like is reduced in the bonded interface in subsequent processes.

The recessed portions may be formed by a plurality of dot recessed portions provided so that the dot recessed portions are distant from one another.

According to the above configuration, since the recessed portions are formed by the plurality of dot recessed portions provided so that the dot recessed portions are distant from one another, entering of chemicals, dust, and the like is specifically reduced in the bonded interface in subsequent processes.

The recessed portions may be configured to be alignment marks for aligning the substrate and the semiconductor element part.

According to the above configuration, the recessed portions are the alignment marks for aligning the substrate and the semiconductor element part, thereby making it possible to reduce the trapping of the air bubbles in the bonded interface, and precisely bond the semiconductor element part to the substrate without adding manufacturing processes.

The substrate may be made of glass, and the semiconductor element part may be made of silicon.

According to the above configuration, the substrate is made of glass, and the semiconductor element part is made of silicon, and therefore, for example, the semiconductor element part constituting a TFT, a drive circuit, or a control circuit or the like is specifically bonded to an active matrix substrate made of glass and constituting a liquid crystal display device.

A method of manufacturing a semiconductor device according to the present invention includes: an element formation step of, after forming an element pattern in a substrate layer, forming a flattening film so that the flattening film covers the element pattern; a splitting layer formation step of forming a splitting layer in the substrate layer on which the flattening film is formed; a substrate layer disposition step of disposing, in a predetermined position of a substrate for bonding, the substrate layer in which the element pattern and the splitting layer are formed; and a substrate layer separation step of separating a part of the substrate layer disposed on the substrate which is located opposite to the substrate along the splitting layer to form a semiconductor element part, wherein the method further includes a recessed portion formation step of etching a surface of at least of one of the flattening film and the substrate to form recessed portions on the surface.

According to the above method, the device transfer technique having the element formation step, the splitting layer formation step, the substrate layer disposition step, and the substrate layer separation step includes the recessed portion formation step of forming the recessed portions in at least one of the substrate and the semiconductor element part in the bonded interface between the substrate and the semiconductor element part. Therefore, the recessed portions formed in the bonded interface reduce local unevenness of the bonding energy in the bonded interface. With this feature, in the recessed portion formation step, only the formation of the recessed portions in at least one of the substrate and the semiconductor element part allows the semiconductor element part to be bonded to the substrate by bonding energy having a relatively predetermined strength in the bonded surface, thereby easily reducing trapping of the air bubbles in the bonded interface. The trapping of the air bubbles is reduced in the bonded interface, thereby reducing deformation of the element pattern formed in the semiconductor element part to reduce damage to the element patterns. Therefore, the trapping of the air bubbles can be easily reduced in the bonded interface, thereby making it possible to reduce damage to the element pattern. In the recessed portion formation step, only the formation of the recessed portions in at least one of the substrate and the semiconductor element part causes reduction of the trapping of the air bubbles in the bonded interface, and therefore, it is unnecessary to prepare a vacuum environment or an environment of high pressure and high temperature in order to perform the bonding process, thereby making it possible to simplify a bonding device or shorten a fabrication process.

In the splitting layer formation step, splitting ions may be implanted into the substrate layer, and after the splitting layer formation step, the recessed portion formation step may be performed.

According to the above method, the recessed portion formation step is performed after the splitting layer formation step. Therefore, for example, in a case of etching the surface of the flattening film in the recessed portion formation step, the recessed portions are not formed in the surface of the substrate layer (flattening film) when splitting layer is formed in the substrate layer in the splitting layer formation step. Therefore, when the splitting ions are implanted into the substrate layer in the splitting layer formation step, since the surface into which the ions are implanted is flat, implantation depths of the splitting ions are constant in the substrate layer, and when the semiconductor element part is formed in the substrate layer separation step, the splitting layer for splitting the substrate layer is reliably formed within the silicon substrate at the predetermined depth.

### ADVANTAGES OF THE INVENTION

According to the present invention, in the bonded interface, recessed portions are formed in at least one of a substrate for bonding and a semiconductor element part, and therefore, the trapping of the air bubbles can be easily reduced in the bonded interface, thereby making it possible to reduce the damage to the element patterns.

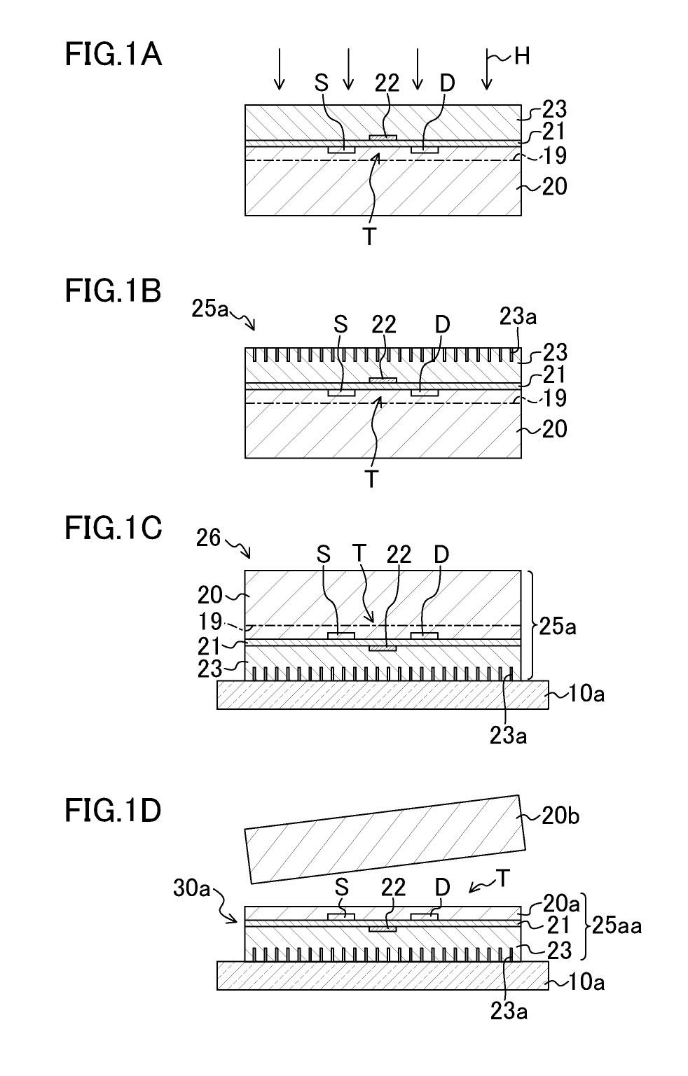

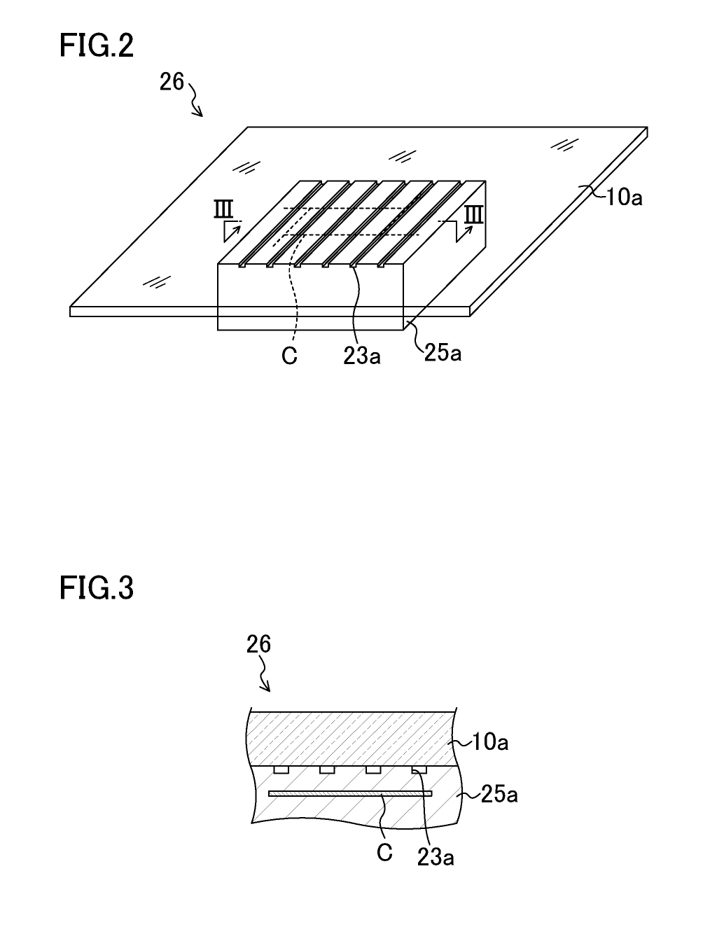

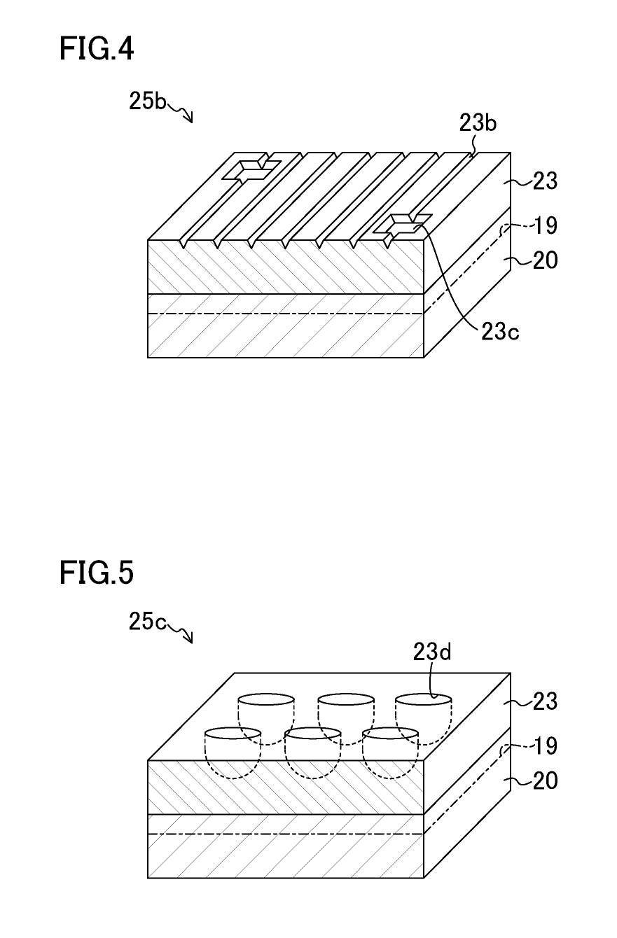

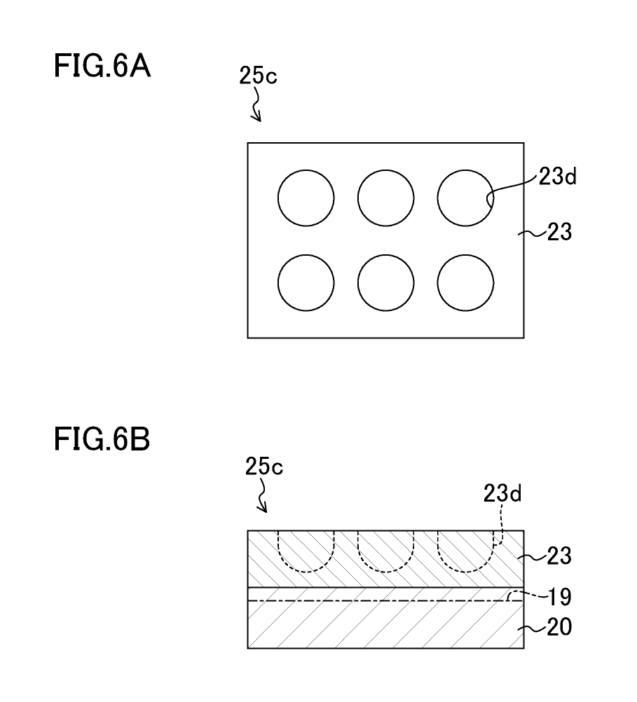

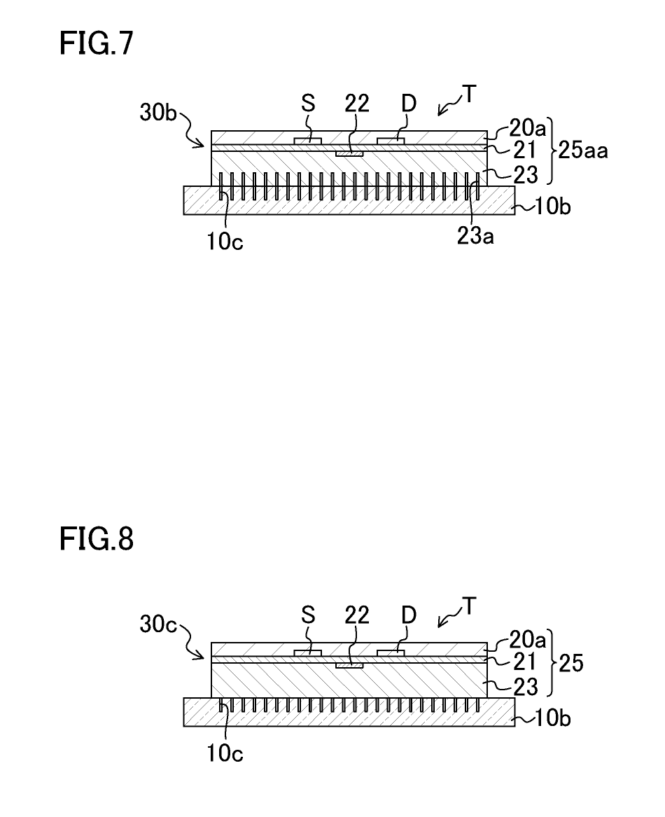

### BRIEF DESCRIPTION OF THE DRAWINGS

[FIG. 1] FIG. 1 is a cross-sectional view showing a method of manufacturing a semiconductor device 30a according to a first embodiment.

[FIG. 2] FIG. 2 is a perspective view of a precursor 26 for manufacturing the semiconductor device 30a.

[FIG. 3] FIG. 3 is a cross-sectional view of the precursor 26 taken along line III-III in FIG. 2.

[FIG. 4] FIG. 4 is a perspective view of a silicon die 25b used for a method of manufacturing a semiconductor device according to a second embodiment.

[FIG. 5] FIG. 5 is a perspective view of a silicon die 25c used for a method of manufacturing a semiconductor device according to a third embodiment.

[FIG. 6] FIG. 6 is a top view (a) and a side view (b) of the silicon die 25c.

[FIG. 7] FIG. 7 is a cross-sectional view showing a semiconductor device 30b according to a fourth embodiment.

[FIG. 8] FIG. 8 is a cross-sectional view showing a semiconductor device 30c according to a fifth embodiment.

[FIG. 9] FIG. 9 is a cross-sectional view showing a method of manufacturing a semiconductor device by using a conventional device transfer technique.

[FIG. 10] FIG. 10 is a cross-sectional view of a precursor 126 of the semiconductor device in the method of manufacturing the semiconductor device by using the conventional device transfer technique.

### DESCRIPTION OF EMBODIMENTS

Embodiments of the present invention will be described hereinafter in detail with reference to the accompanying drawings. The present invention is not limited to the following embodiments.

### First Embodiment

FIGS. 1-3 show a first embodiment of the semiconductor devices and the manufacturing methods thereof according to the present invention. Specifically, FIG. 1 is a cross-sectional view showing a method of manufacturing a semiconductor device 30a in this embodiment. FIG. 2 is a perspective view of a precursor 26 of the semiconductor device 30a. FIG. 3 is a cross-sectional view of the precursor 26 taken along line III-III in FIG. 2.

The semiconductor device 30a includes, as shown in FIG. 1(d), a glass substrate 10a provided as a substrate for bonding, and a semiconductor element part 25aa provided on the glass substrate 10a, and bonded to the glass substrate 10a by Van der Waals force.

The semiconductor element part 25aa includes, as shown in FIG. 1(d), a flattening film 23 in which a plurality of groove lines 23a are formed in the bottom surface of the flattening film 23 so that the groove lines 23a extend in parallel relation to one another, a gate electrode 22 provided in the flattening film 23, a gate insulating film 21 provided on the flattening film 23 so that the gate insulating film 21 covers the gate electrode 22, and a silicon substrate layer 20a provided on the gate insulating film 21, and provided with a source region R and a drain region D so that the source region R and the drain region D are distant from each other with the gate electrode 22 interposed therebetween. The gate electrode 22, and the source region R and the drain region D provided on the gate electrode 22 through the gate insulating film 21 constitute a transistor element T (element pattern), as shown in FIG. 1(d).

In each of the groove lines 23a formed in the flattening film 23, its width, depth, and pitch are set so that a ratio of the total area occupied by the groove lines 23a to the area of the bonded surface in the semiconductor element part 25aa is up to about 70% (preferably up to 50%). Since this ratio depends on elements, such as the pattern shape (a lattice shape, a stripe shape or the like) of the plurality of the groove lines 23a formed in the flattening film 23, or flatness and material properties of the flattening film, the width, depth, and pitch necessary for each of the groove lines 23a in the flattening film 23 depend on these elements.

Next, one example of the method of manufacturing the semiconductor device 30a having the above structure will be described. The method of manufacturing the semiconductor device 30a in this embodiment includes an element formation step, a splitting layer formation step, a recessed portion formation step, a substrate layer disposition step, and a substrate layer separation step.

### Element Formation Step

First, a silicon substrate 20 which is a substrate layer is treated in a high temperature atmosphere to allow a silicon oxide film to grow on the surface of the silicon substrate 20, thereby forming the gate insulating film 21.

Next, after formation of, for example, a polysilicon film on the entirety of the substrate on which the gate insulating film 21 is formed by a plasma CVD (Chemical Vapor Deposition) method, a photolithographic patterning of the polysilicon film is performed, thereby forming a gate electrode 22.

Then, phosphorus ions are implanted into the silicon substrate 20 by using a gate electrode 22 or the like as a mask, thereby forming the source region S and the drain region D on the surface of the silicon substrate 20 to form the transistor element T.

Next, after formation of, for example, a silicon oxide film on the entirety of the substrate on which the transistor element T is formed by a plasma CVD method, the silicon oxide film is flattened by a CMP (Chemical Mechanical Polishing) method, thereby forming the flattening film 23 covering the transistor element T.

### Splitting Layer Formation Step

As shown in FIG. 1(a), splitting ions H, such as hydrogen or helium, are implanted into the silicon substrate 20 on which the transistor element T and the flattening film 23 are formed in the above element formation step, thereby forming a splitting layer 19 within the silicon substrate 20 at a predetermined depth.

### Recessed Portion Formation Step

On the surface of the flattening film 23 on the silicon substrate 20 in which the splitting layer 19 is formed in the above splitting layer formation step, after a resist pattern (not shown) is formed, a part of the flattening film 23 exposed from the resist pattern is dry etched or wet etched, thereby forming the plurality of the groove lines 23a as the recessed portions to form a silicon die 25a, as shown in FIG. 1(b).

### Substrate Layer Disposition Step

The silicon die 25a formed in the above recessed portion formation step is disposed on a predetermined position of the glass substrate 10a, thereby bonding the silicon die 25a to the surface of the substrate 10a by Van der Waals force to form a precursor 26, as shown in FIGS. 1(c), 2, and 3. In a bonded interface between the glass substrate 10a and the silicon die 25a in the precursor 26, the respective groove lines 23a formed in the flattening film 23 reduce trapping of air bubbles, as shown in FIG. 3. FIG. 2 is a perspective view of the precursor 26 of FIG. 1(c) viewed from the side of the glass substrate 10a so that the respective groove lines 23a formed in the flattening film 23 are easily recognized.

### Substrate Layer Separation Step

The precursor 26 formed in the above substrate layer disposition step is annealed at a temperature of substantially 500° C., thereby cleaving and separating the silicon substrate 20 into the silicon substrate layer 20a and a substrate layer 20b to be thrown away along the splitting layer 19 to from the semiconductor element part 25aa.

In this way, the semiconductor device 30a in this embodiment can be manufactured.

As stated above, according to the semiconductor device and manufacturing method thereof in this embodiment, since the device transfer technique having the element formation step, the splitting layer formation step, the substrate layer disposition step, and the substrate layer separation step includes the recessed portion formation step of forming the plurality of the groove lines 23a in the semiconductor element part 25aa located in the bonded interface between the glass substrate 10a and the semiconductor element part 25aa, the respective groove lines 23a formed in the bonded interface can reduce local unevenness of the bonding energy in the bonded interface. With this feature, in the recessed portion formation step, only the formation of the plurality of the groove lines 23a in the surface of the flattening film 23 in the silicon die 25a which is to be the semiconductor element part 25aa allows the semiconductor element part 25aa (silicon die 25a) to be bonded to the glass substrate 10a by bonding energy having a relatively predetermined strength in the bonded surface, thereby making it possible to easily reduce trapping of the air bubbles in the bonded interface. The trapping of the air bubbles can be reduced in the bonded interface, thereby making it possible to reduce deformation of a circuit portion C including the transistor element T and the like formed in the semiconductor element part 25aa to be able to reduce damage to the transistor element T. Therefore, the trapping of the air bubbles can be easily reduced in the bonded interface, thereby making it possible to reduce the damage to the transistor element T. In the recessed portion step, only the formation of the plurality of the groove lines 23a in the silicon die 25a which is to be the semiconductor element part 25aa causes reduction of the trapping of the air bubbles in the bonded interface, and therefore, it is unnecessary to prepare a device for holding the glass substrate 10a and the silicon die 25a under a vacuum atmosphere or a device for applying a high pressure or a high temperature to the silicon die 25a in order to perform the bonding process, thereby making it possible to simplify a bonding device or shorten a fabrication process.

According to the manufacturing method of the semiconductor device 30a in this embodiment, the recessed portion formation step is performed after the splitting layer formation step, and therefore, when the splitting layer 19 is formed in the silicon substrate 20 in the splitting layer formation step, the recessed portions are not formed in the surface of the silicon substrate 20 (flattening film 23). Therefore, when the splitting ions H are implanted into the silicon substrate 20 in the splitting layer formation step, since the surface into which the ions are implanted is flat, implantation depths of the splitting ions H are constant in the silicon substrate 20, and when the semiconductor element part 25aa is formed in the substrate layer separation step, the splitting layer 19 for splitting the silicon substrate 20 is surely formed within the silicon substrate 20 at the predetermined depth.

According to the semiconductor device 30a in this embodiment, the recessed portions in the flattening film 23 are the plurality of the groove lines 23a provided such that each of the groove lines 23a communicates with the outside, and the groove lines 23a extend in parallel relation to each other, and therefore, the air bubbles that may be trapped in the bonded interface can be exhausted to the outside through the end portions of the respective groove lines 23a. Furthermore, even if hydrogen gas is diffused not only in the aforementioned bonding process but also in the subsequent anneal process and the cleaving process, the occurrence of air bubbles can be reduced in the bonded interface.

The embodiment exemplifies the method of manufacturing the semiconductor device 30a of forming one transistor element T in the silicon substrate 20 to form the silicon die 25a. However, the present invention is also applicable for a method of, after forming in the silicon substrate lots of element patterns, such as a transistor element, splitting the silicon substrate into the respective element patterns, thereby forming a plurality of the silicon dies at the same time.

### Second Embodiment

FIG. 4 is a perspective view of a silicon die 25b used for a method of manufacturing a semiconductor device in this embodiment. In each of the embodiment indicated below, the same reference characters as those shown in FIGS. 1-3 are used to represent identical elements, and the explanation thereof will be omitted.

In the silicon die 25a used in the manufacturing method in the first embodiments, the plurality of the groove lines 23a are formed in the surface of the flattening film 23. However, the silicon die 25b used in the manufacturing method of this embodiment includes, as shown in FIG. 4, not only the plurality of the groove lines 23b but also alignment marks 23c in the surface of the flattening film 23. Although each of the groove lines 23a in the first embodiment has a substantially U-shaped cross section, each of the groove lines 23b in this embodiment has a substantially V-shaped cross section.

The silicon die 25b can be prepared by changing the shape of the resist pattern used when the flattening film 23 is etched in the recessed portion formation step in the manufacturing method in the first embodiment, and forming the respective groove lines 23b and the alignment marks 23c at the same time. In this embodiment, a rectangular shaped mark is exemplified as the alignment mark 23c. It may have a circular shape or other polygonal shapes.

According to the manufacturing method of the semiconductor device using the silicon die 25b in this embodiment, as well as the first embodiment, the groove lines 23b in the flattening film 23 constituting the semiconductor element part are formed, and therefore, trapping of the air bubbles is easily reduced in the bonded interface, thereby making it possible to reduce damage to the transistor element. Besides, since the alignment marks 23c are formed in the bonded interface, the silicon die 25b to be the semiconductor element part can be precisely bonded to the glass substrate without adding manufacturing processes.

### Third Embodiment

FIG. 5 is a perspective view of a silicon die 25c used for a method of manufacturing a semiconductor device in this embodiment, and FIG. 6 is a top view (a) and a side view (b) of the silicon die 25c.

Although in the silicon dies 25a and 25b used in the manufacturing methods in the first and second embodiments, the recessed portions communicate with the outside, the silicon die 25c used in the manufacturing method in this embodiment includes the recessed portions which do not communicate with the outside.

Specifically, as shown in FIGS. 5 and 6, the silicon die 25c is provided with a plurality of dot recessed portions 23d in the flattening film 23 so that the dot recessed portions 23d are distant from one another.

The silicon die 25c can be prepared by changing the shape of the resist pattern used when the flattening film 23 is etched in the recessed portion formation step in the manufacturing method in the first embodiment, and forming the dot recessed portions 23d.

According to the manufacturing method of the semiconductor device using the silicon die 25c in this embodiment, as well as the first and second embodiments, the dot recessed portions 23d in the flattening film 23 constituting the semiconductor element part are formed, and therefore, trapping of the air bubbles is easily reduced in the bonded interface, thereby making it possible to reduce damage to the transistor element. Besides, the recessed portions in the flattening film 23 are the plurality of the dot recessed portions 23d provided such that the dot recessed portions 23d do not communicate with the outside and are distant from one another, thereby making it possible to reduce entering of chemicals, dust, and the like into the bonded interface in subsequent processes.

### Fourth Embodiment

FIG. 7 is a cross-sectional view showing a semiconductor device 30b in this embodiment.

In the semiconductor devices in the first, second, and third embodiments, the recessed portions for reducing the deformation of the transistor element are provided only in the surface of the flattening film 23 constituting the silicon die 25a, 25b, or 25c which is to be the semiconductor element part. However, in the semiconductor device 30b in this embodiment, the recessed portions are formed not only in the surface of the semiconductor element part 25aa, but also in the surface of the glass substrate 10b.

Specifically, the semiconductor device 30b includes, as shown in FIG. 7, a glass substrate 10b provided as a substrate for bonding, and a semiconductor element part 25aa provided on the glass substrate 10b and bonded to the glass substrate 10a by Van der Waals force.

The glass substrate 10b is provided with a plurality of the groove lines 10c so that the groove lines 10c extend in parallel relation to one another in the bonded interface.

In addition to the etching of the flattening film 23 in the recessed portion formation step of the manufacturing method in the first embodiment, the glass substrate 10b can be prepared by forming a resist pattern in a region which is to be the bonded interface in the glass substrate 10b, and dry etching or wet etching a part of the flattening film 23 exposed from the resist pattern to form the respective groove lines 10c.

According to the semiconductor device 30b in this embodiment, the respective groove lines 23a are formed in the flattening film 23 constituting the semiconductor element part 25aa, and besides, the respective groove lines 10c are formed in the glass substrate 10b, thereby easily reducing trapping of the air bubbles in the bonded interface to make it possible to reduce damage to the transistor element.

### Fifth Embodiment

FIG. 8 is a cross-sectional view showing a semiconductor device 30c in this embodiment.

In the semiconductor devices in the first through fourth embodiments, recessed portions for deforming the transistor element are formed at least in the surface of the flattening film 23 constituting the semiconductor element part. In the semiconductor device 30c in this embodiment, the recessed portions are formed only in the surface of the glass substrate 10b.

Specifically, the semiconductor device 30c includes, as shown in FIG. 8, a glass substrate 10b provided as a substrate for bonding, and a semiconductor element part 25 provided on the glass substrate 10b and bonded to the glass substrate 10b by Van der Waals force.

As shown in FIG. 8, the semiconductor element part 25 has substantially the same structure as in the semiconductor element part 25aa described in the first embodiment other than a structure in which the recessed portions are not formed in the surface of the flattening film 23.

According to the semiconductor device 30c in this embodiment, the respective groove lines 10c are formed in the glass substrate 10b, thereby easily reducing trapping of the air bubbles in the bonded interface to make it possible to reduce damage to the transistor element.

Each of the embodiments exemplifies the method of implanting the splitting ions into the substrate layer to form the splitting layer within the substrate layer. However, the splitting layer may be formed by forming, within the substrate layer, a porous layer, an amorphous layer, and a layer having a relatively weak structure, such as a columnar structure.

Each of the embodiments exemplifies the glass substrate as the substrate. However, a plastic substrate, a metal plate, or the like may be used as the substrate. In the substrate, a thin film silicon device may be formed in advance, and the thin film silicon device may be formed in the substrate after the semiconductor element part is bonded to the substrate.

Each of the embodiments exemplifies the circuit portion including the transistor element, and the like, as an element pattern to be transferred. However, only a thin film pattern constituting a part of the circuit portion may be used as the element pattern.

### INDUSTRIAL APPLICABILITY

As described above, the present invention can easily reduce the trapping of the air bubbles in the bonded interface, thereby making it possible to reduce the damage to the element patterns. Therefore, the present invention is useful for, for example, liquid crystal display devices manufactured by using device transfer techniques.

### DESCRIPTION OF REFERENCE CHARACTERS

H Splitting Ions

C Circuit Portion (Element Pattern)

T Transistor Element (Element Pattern)

10a, 10b Glass Substrate (Substrate for Bonding)

10c, 23a, 23b Groove Line (Recessed Portion)

19 Splitting Layer

20 Silicon Substrate (Substrate Layer)

23 Flattening Film

23c Alignment Mark (Recessed Portion)

23d Dot Patterned Recessed Portions

25, 25aa Semiconductor Element Part

30a-30c Semiconductor Device

1. A semiconductor device, comprising:
a substrate for bonding; and
a semiconductor element part which is bonded to the substrate, and in which an element pattern is formed,
wherein
in a bonded interface between the substrate and the semiconductor element part, recessed portions are formed in at least one of the substrate and the semiconductor element part.

2. The semiconductor device of claim 1, wherein
the recessed portions communicate with an outside.

3. The semiconductor device of claim 2, wherein
the recessed portions are formed by a plurality of groove lines extending in parallel relation to one another.

4. The semiconductor device of claim 1, wherein
the recessed portions do not communicate with an outside.

5. The semiconductor device of claim 4, wherein
the recessed portions are formed by a plurality of dot recessed portions provided so that the dot recessed portions are distant from one another.

6. The semiconductor device of claim 1, wherein
the recessed portions are configured to be alignment marks for aligning the substrate and the semiconductor element part.

7. The semiconductor device of claim 1, wherein
the substrate is made of glass, and
the semiconductor element part is made of silicon.

8. A method of manufacturing a semiconductor device, the method comprising:
an element formation step of, after forming an element pattern in a substrate layer, forming a flattening film so that the flattening film covers the element pattern;
a splitting layer formation step of forming a splitting layer in the substrate layer on which the flattening film is formed;
a substrate layer disposition step of disposing, in a predetermined position of a substrate for bonding, the substrate layer in which the element pattern and the splitting layer are formed; and
a substrate layer separation step of separating a part of the substrate layer disposed on the substrate which is located opposite to the substrate along the splitting layer to form a semiconductor element part,
wherein
the method further includes a recessed portion formation step of etching a surface of at least of one of the flattening film and the substrate to form recessed portions in the surface.

9. The method of claim 8, wherein
in the splitting layer formation step, splitting ions are implanted into the substrate layer, and
after the splitting layer formation step, the recessed portion formation step is performed.
